(19) United States
(12) Patent Application Publication
(10) Pub. No.: US 2025/0337406 A1
(43) Pub. Date: Oct. 30, 2025

(54) RADIO FREQUENCY SWITCH AND METHOD

(71) Applicant: STMicroelectronics International N.V., Geneva (CH)

(72) Inventors: Guillaume Blamon, Courbevoie (FR); Gabriel Rohi, Isere (FR)

(21) Appl. No.: 19/172,344

(22) Filed: Apr. 7, 2025

(30) Foreign Application Priority Data
Apr. 26, 2024 (FR) FR2404374

(51) Int. Cl. H03K 17/16; H03K 17/00

(52) U.S. Cl. CPC H03K 17/161; H03K 17/007

(57) ABSTRACT

The present description concerns a radio frequency switch comprising a control circuit configured to, in a radio frequency signal transmit mode, control a switching circuit with a first state originating from an output of a charge pump circuit, and, in a radio frequency signal receive mode, disable the charge pump circuit and control the switching circuit with a second state originating from a reference voltage.

### CROSS-REFERENCE TO RELATED APPLICATIONS

This application claims priority to French Application No. 2404374, filed on Apr. 26, 2024, which application is hereby incorporated herein by reference.

### TECHNICAL FIELD

The present disclosure generally concerns radio frequency switches and methods of operating these switches.

### BACKGROUND

Radio frequency systems use, in certain half-duplex architectures, radio frequency switches to alternately couple a same antenna to a radio frequency signal transmit circuit and then to a radio frequency signal receive circuit.

In the case where these radio frequency switches are formed with a silicon-on-insulator (SOI) technology, the signals driving them may generate interference during the use of the receive circuit.

### SUMMARY

There exists a need to provide a radio frequency switch generating no spurious signals in the receive circuit.

An embodiment overcomes all or part of the disadvantages of known switches.

An embodiment provides a radio frequency switch comprising a control circuit configured to: in a radio frequency signal transmit mode, control a switching circuit with a first state originating from an output of a charge pump circuit; and in a radio frequency signal receive mode, disable the charge pump circuit and control the switching circuit with a second state originating from a reference voltage.

An embodiment provides a method of operation of a radio frequency switch comprising a control circuit, the method comprising: in a radio frequency signal transmit mode, the control of a switching circuit with a first state originating from an output of a charge pump circuit; in a radio frequency signal receive mode, the disabling of the charge pump circuit and the control of the switching circuit with a second state originating from a reference voltage.

According to an embodiment, the control circuit comprises: a first node configured to receive a signal for enabling the transmit mode; and an inverter block coupling the first node to a control node of a first transistor having a first conduction node configured to receive the reference voltage.

According to an embodiment, an output node of the charge pump circuit is coupled to a control node of the switching circuit.

According to an embodiment, a second conduction node of the first transistor is coupled to the output node of the charge pump circuit.

According to an embodiment, the control circuit comprises an oscillator coupling the first node to an input node of the charge pump circuit.

According to an embodiment, the reference voltage is the ground.

According to an embodiment, the first transistor is an NMOS transistor.

According to an embodiment, the charge pump circuit is configured to deliver a negative voltage on its output node when it receives an alternating signal.

According to an embodiment, the inverter block comprises a first and a second inverters; the first inverter being configured to receive another reference voltage on a first power supply node and the ground on the second power supply node, the first inverter further comprising an input node coupled to the first node and an output node coupled to a first power supply node of the second inverter; the second inverter comprising an input node configured to be coupled to ground, an output node coupled to the control node of the first transistor, and a second power supply node coupled to the output node of the charge pump circuit.

According to an embodiment, the reference voltage is VDD.

According to an embodiment, the first transistor is a PMOS transistor.

According to an embodiment, the charge pump circuit is configured to deliver a positive voltage higher than VDD on its output node when it receives an alternating signal.

According to an embodiment, the inverter block comprises an inverter circuit having: an input node configured to receive the reference voltage, a first power supply node coupled to the output node of the charge pump circuit and a second power supply node coupled to the first node; and an output node coupled to the control node of the first transistor.

According to an embodiment, the switching circuit comprises transistors of silicon-on-insulator type.

According to an embodiment, the output node of the charge pump circuit is coupled to the switching circuit via a voltage level shifting circuit reconfigurable according to implementation of the charge pump circuit.

According to an embodiment, the switch comprises a first charge pump circuit and a second charge pump circuit such as described hereabove; the respective output nodes of the first and second charge pump circuits being coupled to the switching circuit via a voltage level shifting circuit reconfigurable according to the implementation of the first or of the second charge pump circuits.

According to an embodiment, the switching circuit comprises: N second transistors coupling a transmit circuit output node to an antenna node; N third transistors coupling the antenna node to an receive circuit input node; N fourth transistors coupling the ground to the transmit circuit output node; and N fifth transistors coupling the ground to the receive circuit input node; the control circuit being configured to control the Nth second and Nth fifth transistors with a respective Nth first signal originating from the voltage level shifting circuit and to control the Nth third and Nth fourth transistors with a Nth second signal complementary to the Nth first signal; N being an integer greater than or equal to 1.

According to an embodiment, N is equal to 1, the switching circuit comprising: a second transistor coupling a transmit circuit output node to an antenna node; a third transistor coupling the antenna node to a receive circuit input node; a fourth transistor coupling the ground to the transmit circuit output node; and a fifth transistor coupling the ground to the receive circuit input node; the control circuit being configured to control the second and fifth transistors with a first signal originating from the voltage level shifting circuit and to control the third and fourth transistors with a second signal complementary to the first signal.

An embodiment provides a radio frequency system comprising a switch such as described hereabove and an antenna coupled to the antenna node.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 shows, very schematically and in the form of blocks, an example of a radio frequency system of the type to which the described embodiments apply;

FIG. 2 shows, very schematically, a circuit of the system of FIG. 1;

FIG. 3 shows a circuit of FIG. 2 according to an embodiment;

FIG. 4 shows a circuit of FIG. 3 according to an embodiment;

FIG. 5 shows a circuit of FIG. 4 according to another operating mode;

FIG. 6 shows the circuit of FIG. 4 or 5 according to an embodiment;

FIG. 7 shows a circuit of FIG. 3 according to an embodiment;

FIG. 8 shows a circuit of FIG. 7 according to an embodiment;

FIG. 9 shows a circuit of FIG. 7 according to an embodiment;

FIG. 10 shows a circuit of FIG. 7 according to an embodiment;

FIG. 11 shows a circuit of FIG. 7 according to an embodiment;

FIG. 12 shows a circuit of FIG. 7 according to an embodiment;

FIG. 13 shows a circuit of FIG. 7 according to an embodiment;

FIG. 14 shows a timing diagram of the operation of a circuit of FIG. 7; and

FIG. 15 shows a circuit of FIG. 3 according to an embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10%, preferably of plus or minus 5%.

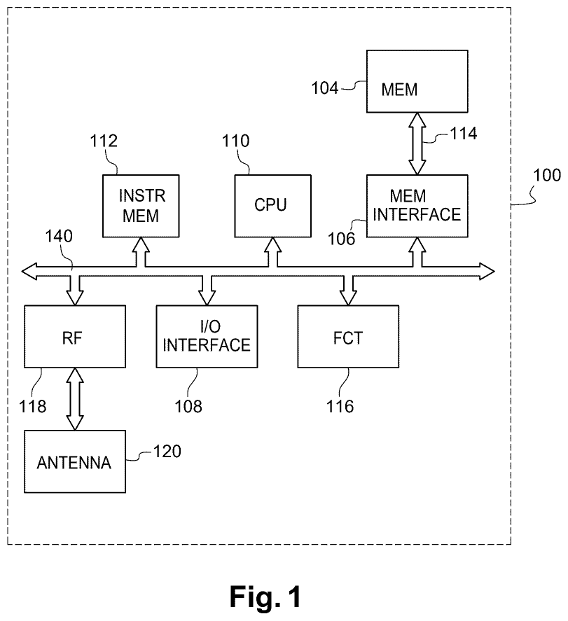

FIG. 1 shows, very schematically and in the form of blocks, an example of a radio frequency system 100 of the type to which the described embodiments apply.

System 100 comprises a memory, for example non-volatile, 104 (MEM), for example of FLASH memory or phase change memory (PCM) type, capable of communicating, via a communication bus 114, with a memory interface 106 (MEM INTERFACE) configured to write or read data into and from memory 104.

System 100 further comprises, for example, a processing unit 110 (CPU) comprising one or a plurality of processors under control of instructions stored in an instruction memory 112 (INSTR MEM). Instruction memory 112 is, for example, a volatile random access memory (RAM). Processing unit 110 and memory 112 communicate, for example, via a system (data, address, and control) bus 140. Non-volatile memory 104 is coupled to system bus 140 via non-volatile memory interface 106 and via bus 114. System 100 further comprises an input/output interface 108 (I/O interface) coupled to system bus 140 to communicate with the outside.

System 100 may integrate other circuits implementing other functions (for example, one or a plurality of volatile and/or non-volatile memories, or other processing units), symbolized by a block 116 (FCT) in FIG. 1. Among these other circuits, system 100 for example comprises a radio frequency signal management circuit 118 (RF) coupled to an antenna circuit 120 (ANTENNA). Circuit 118 is in charge, for example, of the generation, the reception, the routing, and the adaptation of radio frequency signals.

In an example, system 100 forms part of a package dealing with the Internet of Things (IOT), wireless local area networks (WLAN), or even WIFI networks.

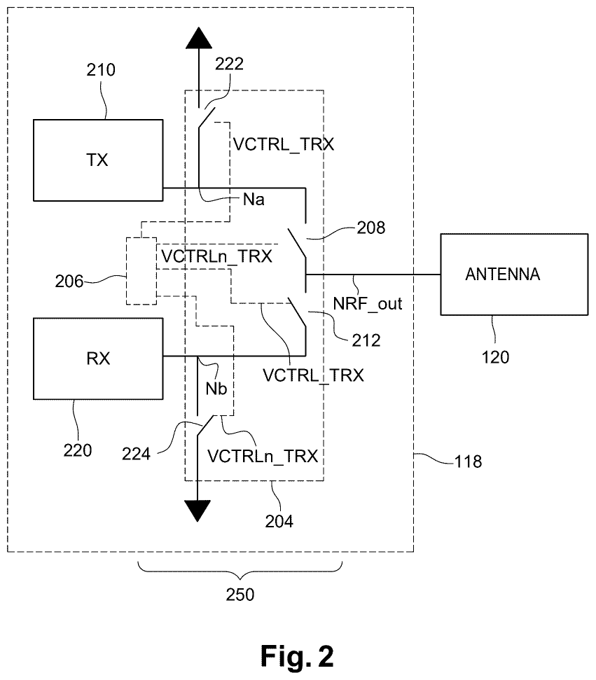

FIG. 2 shows, very schematically, a circuit of the system of FIG. 1. More particularly, the drawing shows an example of circuit 118.

In the shown example, circuit 118 comprises a circuit 210 for transmitting (TX) radio frequency signals and a circuit for receiving 220 (RX) radio-frequency signals. Circuit 210 is coupled to a node Na. Node Na is coupled to a node NRF_out via a switch 208. Node NRF_out is itself coupled, preferably connected, to antenna circuit 120. Circuit 220 is coupled to a node Nb. Node Nb is coupled to node NRF_out via a switch 212. Node Na is coupled to ground via a switch 222. Node Nb is coupled to ground via a switch 224.

Switches 208, 212, 222, and 224 altogether form a switching circuit 204. Switching circuit 204 is controlled by control circuit 206 to form a switch 250.

In an example, not shown, circuit 204 comprises a plurality of circuits similar to the circuit formed by transistors 208, 222 or 212, 224.

In operation, in a radio frequency signal receive mode, control circuit 206 applies complementary control signals VCTRL_TRX and VCTRLn_TRX to transistors 212, 222 and 208, 224 respectively, so that switches 212 and 222 are on, that is, so that they are conductive, and switches 208 and 224 are off, that is, non-conductive.

In a transmit mode, control circuit 206 applies signals VCTRL_TRX and VCTRLn_TRX so that switches 212 and 222 are off, that is, so that they are non-conductive, and switches 208 and 224 are on, that is, conductive. A half-duplex architecture is thus formed in which antenna 120 is alternately coupled to transmit circuit 210 via node Na and then to receive circuit 220 via node Nb.

In the receive mode, the voltages across transistors 208 and 224 are low and the voltages across transistors 212 and 222 are nearly zero while, in transmit mode, the voltages across transistors 212 and 222 are high (for example several volts or tens of volts) and the voltages across transistors 208 and 224 are nearly zero.

In an example, switches 208, 212, 222, and 224 are transistors formed in silicon-on-insulator (SOI) technology. In an example, these transistors are formed in fully depleted silicon-on-insulator (FDSOI) technology. In this case, to be able to withstand the high voltages of the transmit mode applied to transistors 212 and 222, it is necessary to apply a significant negative (in the case of N-type metal-oxide-semiconductor (NMOS) transistors) or positive (in the case of P-type metal-oxide-semiconductor (PMOS) transistors) voltage (for example respectively lower than −VDD or higher than +VDD) to the gates of transistors 212 and 222 to maintain their performance as well as to ensure their non-conductive character in the off state. This high voltage is often obtained, for example, by using charge pumps supplied with an alternating signal such as a clock signal formed based on square waves. The voltages generated by the charge pumps are likely to contain spurious signals in the radio frequency spectrum (spurs). These spurious signals degrade the sensitivity in receive mode of radio frequency systems.

To overcome these disadvantages, the described embodiments provide using the radio frequency switch comprising control circuit 206 configured to: in the transmit mode, control switching circuit 204 with a first state originating from an output of a charge pump circuit; and in the receive mode, disable the charge pump circuit and control switching circuit 204 with a second state originating from a reference voltage.

By the term “state”, there is similarly meant the term “signal” or “voltage to within the value of the gate-source voltage of the transistor”.

This enables to turn off the charge pump circuit during the receive mode when the sensitivity has to be maximum. The spurious signals originating from the operation of the charge pump circuit are thus not generated during the receive mode when the sensitivity has to be high. The reference voltage, applied to the switching circuit while the charge pump circuit is off, enables to maintain the functionality of the system. Although the reference voltage may be lower (in absolute value) than the voltage delivered by the charge pump circuit, during the receive mode the necessary power is much lower than during the transmit mode. When a charge pump circuit is disabled, its output impedance becomes high, which enables to create an isolation with the switching circuit.

The advantage of disabling the charge pump circuit also lies in a lower power consumption and in the fact that a charge pump circuit has a high impedance when it is not enabled.

Another advantage of this solution is that it avoids the use of frequency filters based on resistors and on capacitors which occupy a significant space and are expensive.

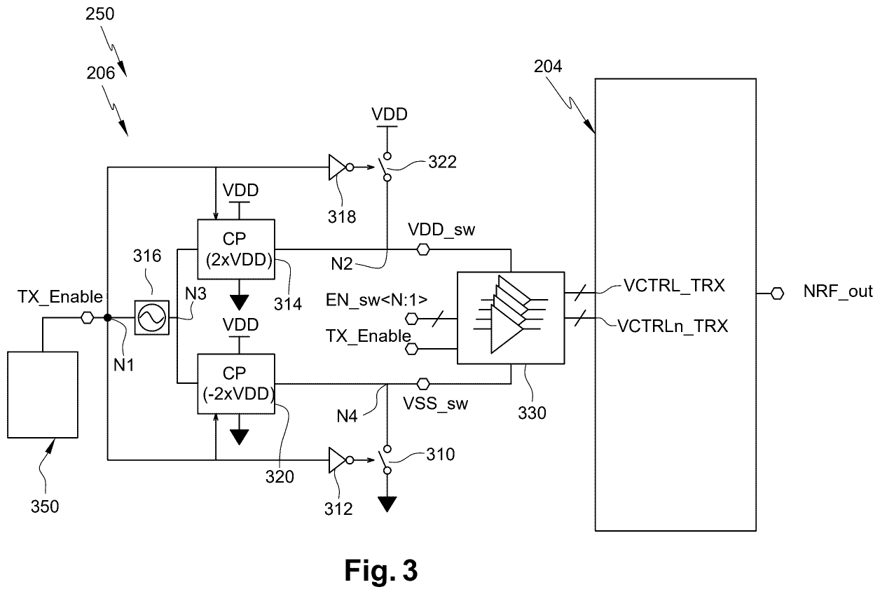

FIG. 3 shows a circuit of FIG. 2 according to an embodiment. More particularly, FIG. 3 shows an example of circuit 206 coupled, preferably connected, to circuit 204.

In the example of FIG. 3, a block 350 delivers a signal TX Enable on a node N1 coupled, preferably connected, to an input of circuit 206. Signal TX Enable is in the high state when the transmit mode is enabled.

In the shown example, circuit 206 comprises two charge pump circuits 314 (CP(2*VDD)), 320(CP(−2*VDD)) both coupled to a power supply voltage rail VDD as well as to ground. The two charge pump circuits 314 and 320 are coupled at their input to a node N3 receiving an alternating signal, for example a clock signal, originating from a circuit 316 coupling node N1 and node N3. The two charge pump circuits 314 and 320 are coupled, preferably connected, to node N1 so as to receive, on an enabling input, signal TX_Enable.

Circuit 314 for example enables to generate a voltage +2*VDD on a node N2 from power supply voltage VDD. Circuit 320 for example enables to generate a −2*VDD voltage on node N4 from voltage VDD.

Circuits 314 and 320 are implemented according to the application, that is, either one or the other is used.

In another, non-illustrated example, a single one of the two charge pump circuits is implemented according to the application.

In the shown example, node N2 is coupled to voltage rail VDD via a switch 322. Switch 322 is controlled by a signal originating from an inverter circuit 318 which is coupled, preferably connected, to node N1. In this example, node N4 is coupled to ground via a switch 310. Switch 310 is controlled by a signal originating from an inverter circuit 312 which is coupled, preferably connected, to node N1.

In the shown example, circuit 206 further comprises a circuit 330 having one or a plurality of reconfigurable driver circuits. Circuit 330 comprises an input coupled, preferably connected, to node N2, N inputs each receiving a respective signal EN_sw<N:1>, an input receiving signal TX Enable, and an input coupled, preferably connected, to node N4. Circuit 330 for example comprises two outputs on which signals VCTRL_TRX and VCTRLn_TRX driving the transistors of circuit 204 are generated. The respective signals EN_sw<N:1> drive the transistors of circuit 204. They are, for example, transmitted by a processing unit (CPU) or are generated by circuit 206.

In the example, not shown, where circuit 204 comprises a plurality of circuits similar to the circuit formed by transistors 208, 222 or 212, 224, each of these circuits receives signals VCTRL_TRX and VCTRLn_TRX in a suitable manner.

Switch 310 is for example implemented by an NMOS-type transistor which forms a pull-down transistor with the substrate of the transistor coupled to the output of charge pump circuit 320.

Switch 322 is formed, for example, by a PMOS-type transistor. This transistor is designated with reference 322 because it has the same function as switch 322. Inverter 318 has a first power supply node configured to receive signal TX Enable and a second power supply node coupled, preferably connected, to node N2. Inverter 318 is configured to receive, on an input node, voltage VDD. Inverter 318 has an output node coupled to a control node of transistor 322. A conduction node of transistor 322, as well as its substrate node, are coupled, preferably connected, to node N2. Another conduction node of transistor 322 is coupled, preferably connected, to a voltage rail configured to receive voltage VDD.

Transistor 322 forms a pull-up transistor. The transistor substrate is coupled to the output of charge pump circuit 314 by node N2. This implies obtaining the highest voltage in transmit mode or in receive mode, voltage Vgs=0 V in transmit mode, since the sources and gates are coupled to the output of charge pump circuit 314, and Vgs=−VDD in the receive mode.

The signal at node N2 is referred to as VDD_sw and the signal at node N4 is referred to as VSS_sw.

In operation, in the case where circuit 320 is implemented: in the transmit mode, signal TX Enable is in the high state (for example VDD), which applies signal VSS_sw to the control node of transistor 310. Signal VSS_sw then is at a zero or negative voltage, for example −VDD or −2*VDD originating from the output of charge pump circuit 320, which makes transistor 310 non-conductive; and in the receive mode, signal TX Enable is in the low state (for example, 0 V), which applies voltage VDD to the control node of transistor 310, which makes transistor 310 conductive. Charge pump circuit 320 is also disabled, and signal VSS_sw thus corresponds to ground.

In the case where circuit 314 is implemented: in the transmit mode, signal TX Enable is in the high state (for example VDD), which applies signal VDD_sw to the control node of transistor 322. Signal VDD_sw then is at a voltage higher than or equal to VDD, for example, 2*VDD which originates from the output of charge pump circuit 314, which makes transistor 322 non-conductive; and in the receive mode, signal TX Enable is in the low state (for example, 0V), which applies a zero voltage to the control node of transistor 322, making transistor 322 conductive. Charge pump circuit 314 is also disabled. As a result, signal VDD_sw is VDD.

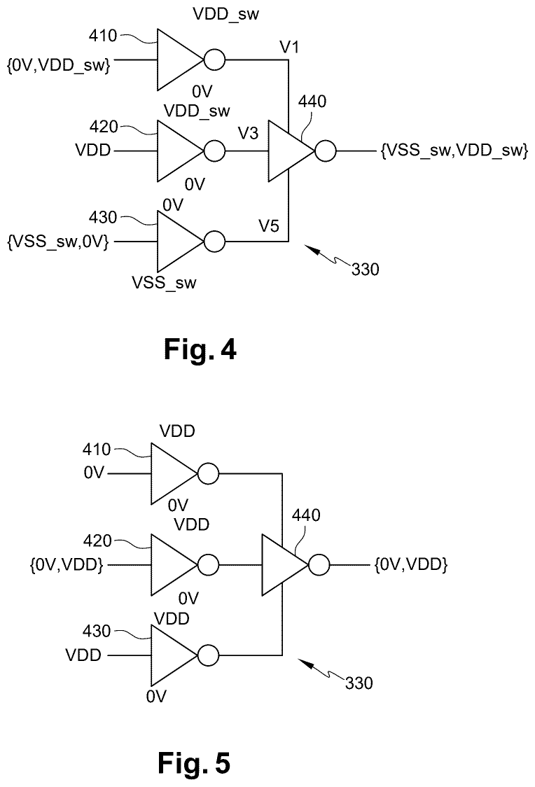

FIG. 4 shows the circuit of FIG. 3 according to an embodiment. More particularly, FIG. 4 shows an example of implementation of circuit 330. FIG. 4 more precisely illustrates the operation of circuit 330 when circuit 320 or 314 is enabled, with the charge pumps active, that is, in transmit mode.

In the shown example, circuit 330 comprises an inverter 440 having a first power supply node coupled, preferably connected, to an output of an inverter 410 to receive a voltage referred to as V1 and a second power supply node coupled, preferably connected, to an output node of an inverter 430 where the voltage is referred to as V5. An input node of inverter 440 is coupled, preferably connected, to an output node of inverter 420 where the voltage is referred to as V3. Signal VCTRL_TRX is applied to an output node of inverter 440. A power supply node of inverter 410 is coupled, preferably connected, to node N2. A power supply node of inverter 430 is coupled, preferably connected, to node N4. An input node of inverter 420 is configured to either receive one of signals EN_sw<N:1>, or to be coupled, preferably connected, to the main power supply rail of circuit VDD.

In an example, circuit 330 comprises N circuits such as that formed by inverters 410, 420, 430, and 440 with the input node of inverter 420 configured to either receive one of signals EN_sw<N:1>, or to be coupled, preferably connected, to the main power supply rail of circuit VDD. Signals EN_sw<N:1> are used as a command for circuit 330 so that the appropriate voltages VTRL_TRX/VTRLn_TRX are applied to the output of circuit 330.

In the transmit mode: inverter 410 has a power supply node configured to receive signal VDD_sw, another power supply node at 0 V, and its input node at o V (in the case where signal EN_SW is in the low state) or VDD_sw (in the case where signal EN_SW is in the high state); inverter 420 has a power supply node configured to receive signal VDD_sw and another power supply node at 0 V and its input node at VDD; and inverter 430 has a power supply node at 0 V and another power supply node configured to receive signal VSS_sw as a reference and its input node configured to receive signal VSS_sw (in the case where signal EN_SW is in the low state) or 0 V (in the case where signal EN_SW is in the high state). Thus, the voltage present at the output of inverter 440, that is, VCTRL_TRX, is VSS_sw (in the case where signal EN_SW is in the low state) or VDD_sw (in the case where signal EN_SW is in the high state).

FIG. 5 shows the circuit of FIG. 3 according to another operating mode. FIG. 5 more specifically illustrates the operation of the circuit 330 of FIG. 3 when circuit 320 or 314 is disabled, that is, in receive mode. In this example, the input node of inverter 420 is configured to receive one of signals EN_sw<N:1>.

In the receive mode: inverter 410 has a power supply node configured to receive VDD, another power supply node is at 0 V, and its input node at 0 V; inverter 420 has a power supply node configured to receive VDD, another power supply node is at 0 V, and its input node is at 0 V (in the case where signal EN_SW is in the low state) or VDD (in the case where signal EN_SW is in the high state); and inverter 430 has a power supply node at VDD, another power supply node at 0 V as a reference, and its input node configured to receive signal VDD. Thus, the voltage present at the output of inverter 440, that is, VCTRL_TRX, is 0 V (in the case where signal EN_SW is in the low state) or VDD (in the case where signal EN_SW is in the high state).

The advantage of the circuit 330 in FIGS. 4 and 5 is that it enables to address both receive and transmit operating modes, be it with a charge pump circuit 314 providing a positive voltage or a charge pump circuit 320 providing a negative output voltage, or both.

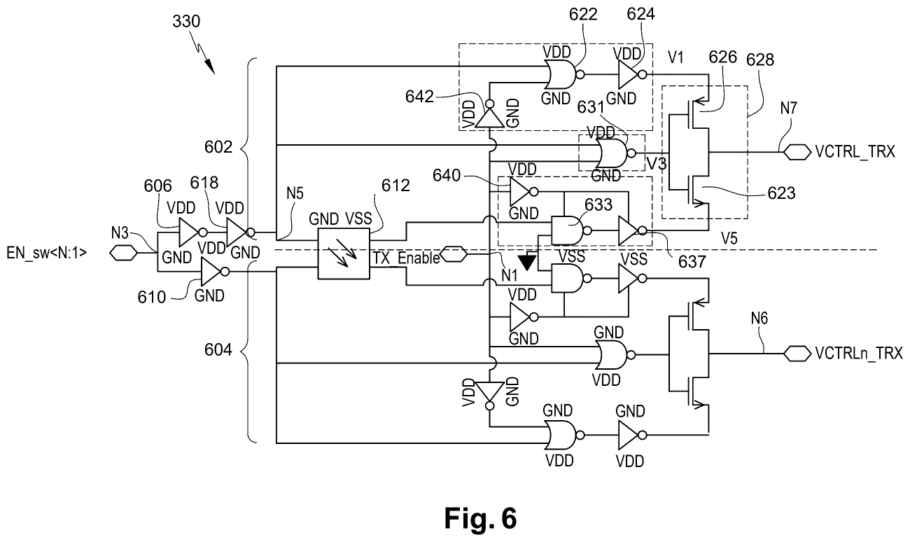

FIG. 6 shows the circuit of FIG. 4 or 5 according to an embodiment.

FIG. 6 comprises an upper portion 602 which represents the generation of voltage VCTRL_TRX and a lower portion 604 which represents the generation of voltage VCTRLn_TRX, and which is similar to the upper portion. Only the upper portion is described in detail hereafter.

In portion 602, a step-down device 612 couples a node N5 to an input node of a logic gate 633 configured to perform a NAND-type logic function based on the signal present on this input node and the ground. Step-down device 612 is configured to, in receive mode, be disabled, that is, its power supply nodes are grounded, and in the transmit mode, shift the voltage domain present at node N5 (for example VDD/GND) towards a lower voltage domain, for example GND/VSS). An output node of gate 633 is coupled, preferably connected, to an input node of inverter 637. Inverter 637 and gate 633 have a power supply node coupled, preferably connected, to an output node of an inverter 640 having an input node coupled, preferably connected, to node N1, as well as another power supply node set to VSS as a reference. Inverter 640 comprises a power supply node configured to be coupled, preferably connected, to VDD and another power supply node configured to be coupled, preferably connected, to ground (GND).

In portion 602, a logic gate 631 is configured to perform a NOR function between the signal TX Enable present on node N1 and that present on node N5. Gate 631 has a power supply node at VDD and another power supply node at ground.

Portion 602 further comprises a logic gate 622 configured to perform a NOR function between the signal present on one of its input nodes coupled, preferably connected, to node N5 and the signal present on another input node which is coupled, preferably connected, to an output node of an inverter 642. Inverter 642 has a power supply node coupled, preferably connected, to VDD and another power supply node coupled, preferably connected, to ground. Inverter 642 has an input node coupled, preferably connected, to node N1. An output node of gate 622 is coupled, preferably connected, to an inverter 624 having a power supply node coupled, preferably connected, to VDD and another supply node coupled, preferably connected, to ground.

In portion 628, an NMOS transistor 623 and a PMOS transistor 626 have a conduction node N7 in common. Another conduction node of transistor 626 is coupled, preferably connected, to the output node of inverter 624, and another conduction node of transistor 623 is coupled, preferably connected, to the output node of inverter 637. The control nodes of transistors 623 and 626 are coupled, preferably connected together and to the output node of gate 631.

In the example of FIG. 6, a node N3 is configured to receive signal EN_sw<N:1>. Node N3 is coupled, preferably connected, to a first branch comprising two inverters 606, 618 in series between node N3 and node N5. Node N3 is coupled, preferably connected, to a second branch comprising an inverter 610 coupling node N3 to portion 604. Inverters 606, 610 and 618 have a power supply node coupled, preferably connected, to VDD and another power supply node coupled, preferably connected, to ground.

Voltage V5 is read from the output node of inverter 637, voltage V3 is read from an output node of logic gate 631, voltage V1 is read from an output node of inverter 624, and signal VCTRL_TRX is read from node N7. Signal VCTRLn_TRX is read from a node N6 of portion 604 equivalent to node N7.

The assembly formed by inverters 624, 642 and gate 622 has the function of forcing V1 to VDD in receive mode and to enable to switch V1 from VDD to ground in transmit mode. The assembly formed by inverters 640, 637 and gate 633 forces V5 to ground in receive mode and enables to switch V5 from ground to VSS in transmit mode.

In operation, signal TX Enable is in the low state during the receive mode, VDD then is, for example, at 1.5 V and VSS is at 0 V. Signal TX Enable is in the high state during the transmit mode, VDD is then raised to, for example, 2.5 V and VSS is lowered to, for example, −2.5 V.

In receive mode, circuit 612 is disabled and: in the case where signal EN_sw<N:1> is at 0, the ground (in other words 0 V) is applied to node N5 and to node N1. V1 and V3 then are at VDD and V5 at ground. VCTRL_TRX then is the ground; in the case where signal EN_sw<N:1> is at 1, node N5 is at VDD and node N1 is grounded. V1 then is at VDD, while V3 and V5 are at ground. VCTRL_TRX then is VDD.

In transmit mode, circuit 612 is enabled and: in the case where signal EN_sw<N:1> is 0, the ground is applied to node N5 and node N1 is at VDD. V1 and V3 then are at ground and V5 at VSS. VCTRL_TRX then is at VSS. In the case where signal EN_sw<N:1> is 1, node N5 and node N1 are at VDD. V1 then is at VDD, while V3 and V5 are at ground. VCTRL_TRX then is VDD.

When the values of the voltages which control switches 208, 212, 222, and 224 are changed, the switching times of the switches are impacted. Indeed, the time constant of the charge of the transistor gates is constant, as well as their threshold voltage. However, the final value of the charge is different, and the charge and discharge curves of the transistor gates differ according to the value of the control voltage. If the control value is close to the threshold voltage, then due to the unchanged time constant of the transistor gate, the gate voltage reaches the threshold later on the charge curve. It would thus be advantageous to be able to limit these changes in the switching time or to minimize the response time from the state change of drive signals EN_sw<N:1>.

The examples of FIGS. 4, 5, and 6 thus implement a digital buffer circuit, materialized by two inverters in series, when one of the charge pump circuits is disabled. The behavior of the circuit of FIG. 6, which acts as a level shifter, is conditioned by digital bit EN_sw<N:1>, which is the same as that which conditions the enabling or disabling of the charge pump circuits.

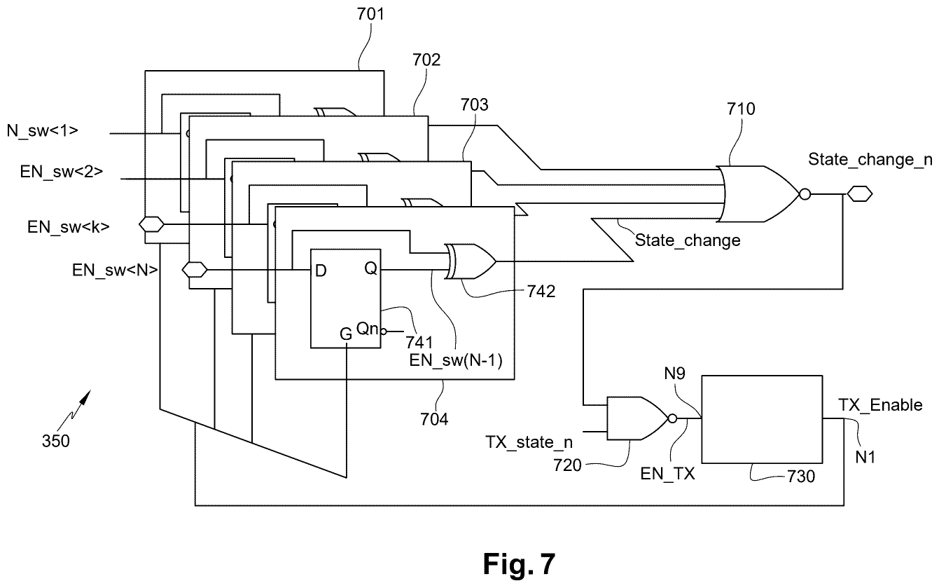

FIG. 7 shows the circuit of FIG. 3 according to an embodiment. More precisely, FIG. 7 illustrates an embodiment of circuit 350. FIG. 7 provides a solution to limit changes in the switching time of transistors.

In the shown example, state change detection circuits 701, 702, 703, and 704 comprise an input node configured to respectively receive control signals EN_sw<1>, EN_Sw<2>, EN_sw<k>, and EN_sw<N>. Each circuit 701, 702, 703, and 704 comprises a flip-flop 741 having a data input D coupled, preferably connected, to a logic gate 742 of exclusive OR (XOR) type and receiving the respective signal EN_sw<1>, EN_sw<2>, EN_sw<k>, or EN_sw<N>. Each flip-flop has its Q output coupled, preferably connected, to an input node of the respective XOR gate 742. The control inputs G of the flip-flops 741 of each of circuits 701, 702, 703, and 704 are coupled, preferably connected, together and to node N1. The respective output signal of each circuit 701, 702, 703, 704 is referred to as State_change. Each output of circuits 701, 702, 703, and 704 is coupled, preferably connected, to a respective input node of a NOR logic gate 710. The output signal of gate 710 is referred to as State_change_n. The output node of gate 710 is coupled, preferably connected, to an input node of a NOR gate 720. Another input node of logic gate 720 is configured to receive a signal Tx_state_n which drives the enabling of the transmit signal of circuit 204. The index “n” of Tx_state_n means that it is an active signal in the low state. Signal Tx_state_n is common to all transmit and receive paths. An output node N9 of gate 720 is coupled, preferably connected, to a delay block 730. The signal at node N9 is referred to as EN_TX. Block 730 has the function of delaying falling edges only. An output node of block 730 is coupled, preferably connected, to node N1 to generate signal TX_enable.

In operation, the previous state of signals EN_sw<N:1> is saved on the D input of the flip-flops and is propagated to the Q outputs. During a state switching of one of signals EN_sw<N:1>, the respective gate 742 compares the new state with the previous one, and changes its output to a high digital state (=1) if the new state is different from the previous state. As a result, signal State_change n is changed to 0 by gate 710 and it is then combined with signal Tx state_n to generate signal TX enable, which enables the charge pump circuit(s). In an example, the charge pumps are all enabled together, which enables to accelerate the switching. In another example, the charge pumps are all switched off to ensure the absence of spurs. The enabling of signal TX enable enables the control gates G of the flip-flops, which causes the update of their output and forces the outputs of all gates 742 to fall back to 0. This will thus disable the charge pump circuit (when the receive mode is enabled) but, since a delay is introduced on the falling edges of signal EN_TX, the charge pump circuit remains active for a few us, which is sufficiently long to enable the gates of the transistors of circuit 204 to charge or discharge once the threshold voltage has been passed.

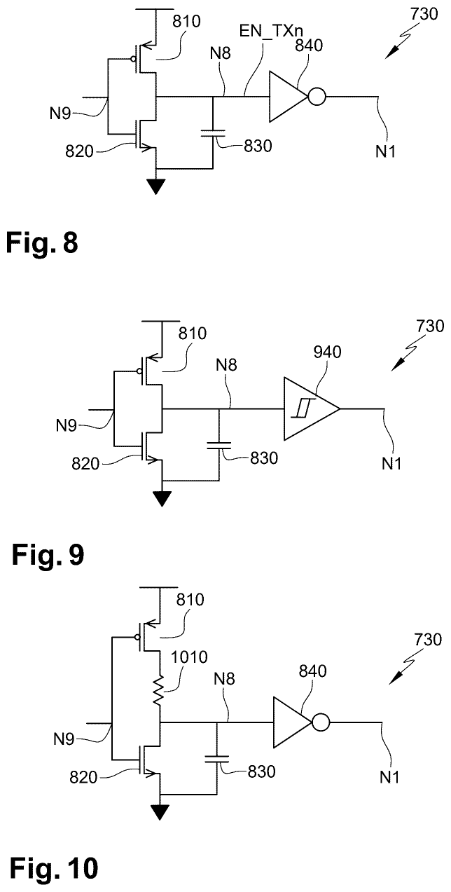

FIGS. 8 to 13 show a circuit of FIG. 7 according to different embodiments. More specifically, FIGS. 8 to 13 show different embodiments of delay circuit 730.

The delay circuit 730 of FIG. 8 comprises a PMOS transistor 810 and an NMOS transistor 820 each having a conduction node coupled, preferably connected, to a node N8, and their respective control nodes coupled, preferably connected, together. Another conduction node of transistor 810 is coupled, preferably connected, to a voltage rail configured to receive voltage VDD, for example, and another conduction node of transistor 820 is coupled, preferably connected, to ground. Node N8 is coupled to ground via a capacitor 830 and coupled to node N1 via an inverter circuit 840.

In an example, the gate width-to-length ratio of transistor 810 is much lower than the gate width-to-length ratio of transistor 820. This enables to have a channel resistance much higher for transistor 810 comparatively to transistor 820. Thus, the time constant formed by the channel resistance and capacitance 830 is much greater when transistor 810 is active than when transistor 820 is active. As a result, node N8 takes longer to charge (that is, to reach VDD) than to discharge (that is, fall to ground GND), and thus to reach the switching threshold of inverter 840. This results in a delay at the output of inverter 840 when the latter switches to the low state.

The delay circuit 730 of FIG. 9 is similar to that of FIG. 8, except that circuit 840 is replaced with a flip-fop 940 of Schmitt trigger type.

The advantage of the circuit of FIG. 9 over that of FIG. 8 is to obtain a decreased noise sensitivity and a more significant induced delay.

The delay circuit 730 of FIG. 10 is similar to that of FIG. 8, except that a resistor 1010 couples the conduction node of transistor 810, which is not connected to VDD, to node N8.

The circuit of FIG. 10 enables to obtain a significant time constant (and thus delay) with a capacitance of reasonable size. Indeed, the gate width-to-length ratio of the transistor is limited for a given technology, and thus the maximum channel resistance of a transistor as well. If it is desired to increase the resistance beyond the technological limit, one has to either add a resistor in series with transistor 810, as in the example of FIG. 10, or connect a plurality of transistors in series.

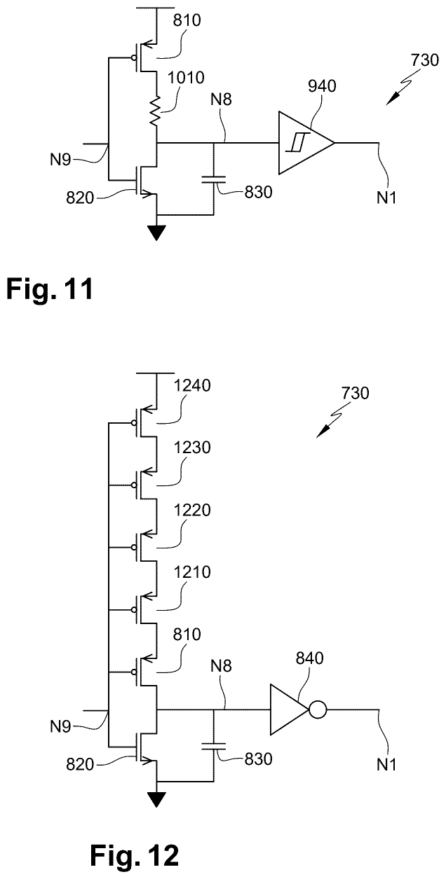

The delay circuit 730 of FIG. 11 is similar to that of FIG. 10, except that circuit 840 is replaced with a flip-flop 940 of Schmitt trigger type.

The advantage of the circuit of FIG. 11 over that of FIG. 10 is that it enables to obtain a decreased sensitivity to noise and greater induced delay. As compared with the example of FIG. 9, it enables to obtain a high time constant (and thus delay) with a capacitance of reasonable size.

The delay circuit 730 of FIG. 12 is similar to that of FIG. 8, except that transistor 810 is coupled to the voltage rail receiving VDD via four PMOS transistors 1210, 1220, 1230, 1240 in series, having their respective control nodes all connected together at node N7. The fact of adding PMOS transistors 1210, 1220, 1230, 1240 enables to increase the channel resistance and thus the time constant as well as the delay of the gate.

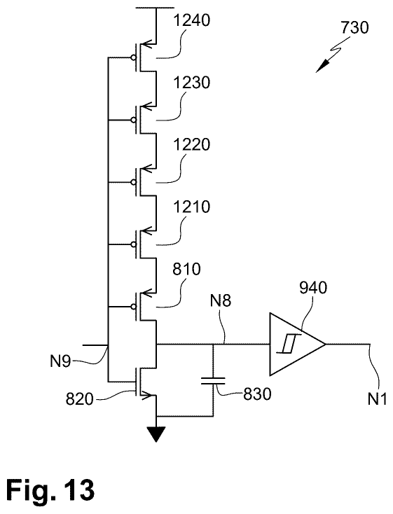

The delay circuit 730 of FIG. 13 is similar to that of FIG. 12, except that inverter 840 is replaced with a Schmitt trigger 940.

In FIGS. 8 to 13, the signal at node N8 is referred to as EN TXn.

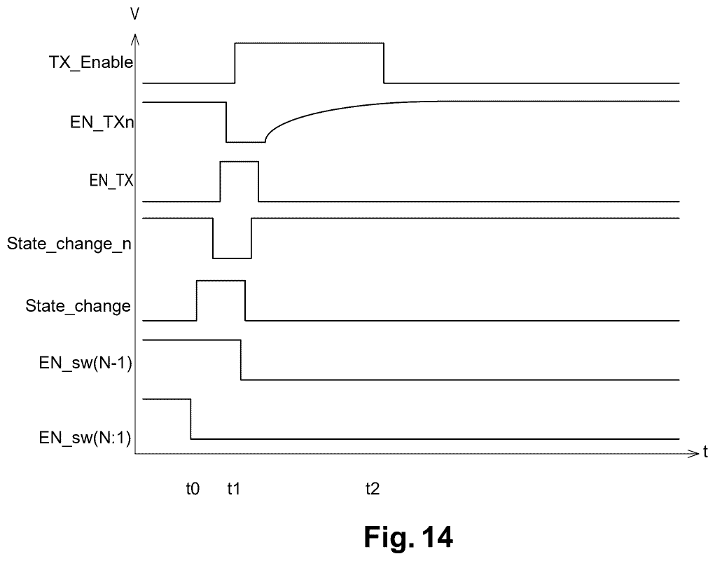

FIG. 14 shows a timing diagram of operation of the circuit of FIG. 7.

More specifically, FIG. 14 shows signals TX Enable, EN_TXn, EN_TX, State change_n, State_change, EN_sw(N-1), and one of signals EN_sw<N:1>.

In the shown example, before a time to, signal TX Enable is in the low state, signal EN_TXn is in the high state, EN_TX signal is in the low state, signal State_change_n is in the high state, signal State_change is in the low state, signal EN_sw<N-1> is in the high state, and signal EN_sw<N:1> is in the high state.

At time to, signal EN_sw<N-1> switches to a low state, which causes the switching to the high state of signal State_change, followed by the switching to the low state of signal State_change_n, then the switching to the high state of signal EN_TX and the switching to the low state of signal EN_TXn and the switching to the high state of signal TX_Enable.

At a time t1, subsequent to to and which corresponds to the time of the enabling, by signal TX_Enable, of the gate G of flip-flops 741, EN_sw(n-1) signal, which corresponds to the previous state of the D inputs, switches to the low state and then remains in the low state. This causes the switching of the corresponding signal State_change to the low state and the switching back to the high state of signal State_change_n. Gate 720 then causes the switching of signal EN_TX to the low state. Circuit 730 then makes signal EN_TXn slowly rise until the level of EN_TXn is sufficiently high to trigger the switching of signal TX_Enable to a low state at a time t2. The various signals of FIG. 14 then for example remain stable until the next state change of a control signal. The time window between times t1 and t2 defines the delay allowing a fast switching of the transistors of circuit 204.

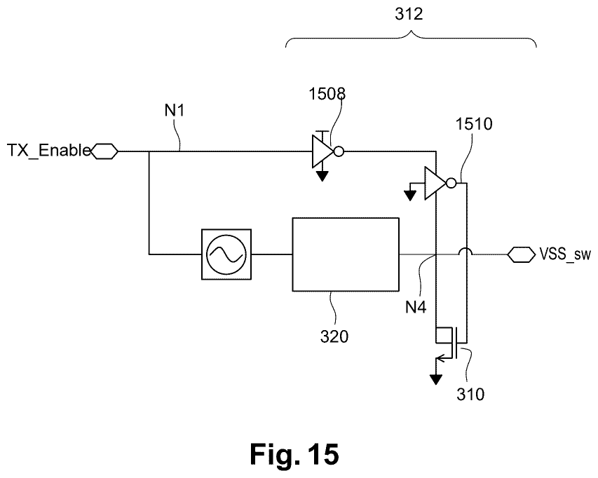

FIG. 15 shows a circuit of FIG. 3 according to an embodiment. More particularly, FIG. 15 shows an implementation of charge pump circuit 320, of circuit 312, and of switch 310.

In the shown example, inverter block 312 is implemented with a first and a second inverter 1508, 1510 and switch 310 is implemented in the form of an NMOS transistor.

First inverter 1508 has a first power supply node coupled, preferably connected, to a voltage rail receiving voltage VDD and a second power supply node coupled, preferably connected, to ground. The first inverter 1508 further comprises an input node coupled, preferably connected, to node N1 and an output node coupled, preferably connected, to a first power supply node of the second inverter 1510.

The second inverter 1510 comprises an input node configured to be coupled to ground, an output node coupled to the control node of transistor 310, and a second power supply node coupled to the output node N4 of charge pump circuit 320.

A conduction node of transistor 310, as well as its substrate node, are coupled, preferably connected, to node N4. Another conduction node of transistor 310 is coupled, preferably connected, to ground.

This enables to obtain the lowest voltage in transmit mode or in receive mode on the substrate node, ensuring that the diode between the substrate and the source remains reverse-biased. The voltage Vgs of the transistor, in transmit mode, is 0 V since the sources and gates are coupled to the output of charge pump circuit 320. In receive mode, Vgs=VDD.

Various embodiments and variants have been described. Those skilled in the art will understand that certain features of these various embodiments and variants may be combined, and other variants will occur to those skilled in the art. In particular, the use of circuit 350 is not mandatory for the operation of the circuit of FIG. 3. Those skilled in the art will be capable of implementing a single one of the two charge pump circuits, according to the needs of the transistors to be controlled. Similarly, a single one of the two portions 602 or 604 of the circuit of FIG. 6 may be implemented, and the possible complementary signal may be generated by any circuit according to the abilities of those skilled in the art.

Finally, the practical implementation of the described embodiments and variants is within the abilities of those skilled in the art based on the functional indications given hereabove. In particular, switches 310 or 322 and the respective inverters 312 and 318 may be implemented in another way than that disclosed in FIG. 6. Similarly, delay circuit 730 may be implemented in other ways than those disclosed in FIGS. 8 to 13, provided for this to enable to obtain a time window where signal TX_Enable temporarily switches from the low state to the high state before falling back to the low state to define a time window allowing a rapid switching of the transistors of circuit 204.

Even though two mutually exclusive radio frequency paths RX, TX have been described, those skilled in the art may consider implementing N mutually exclusive RX-type paths and N mutually exclusive TX-type paths. In this case, switching circuit 204 comprises: N second transistors 208 coupling an output node of a transmit circuit (Na) to antenna node NRF_out; N third transistors 212 coupling the antenna node (NRF_out) to the input node Nb of a receive circuit; N fourth transistors 222 coupling the ground to the output node Na of a transmit circuit; and N fifth transistors 224 coupling the ground to the receive circuit input node Nb, N being an integer greater than or equal to 1.

In this case, control circuit 206 controls the Nth second and Nth fifth transistors 208, 224 with a respective Nth first signal VCTRL_TRX<N> originating from the voltage level shifting circuit 330 and also controls the Nth third and Nth fourth transistors 212, 222 with an Nth second signal VCTRLn_TRX<N> complementary to the Nth first signal VCTRL_TRX<N>.

What is claimed is:

1. A radio frequency switch comprising:
a control circuit configured to:
in a radio frequency signal transmit mode, control a switching circuit with a first state originating from an output of a charge pump circuit; and
in a radio frequency signal receive mode, disable the charge pump circuit and control the switching circuit with a second state originating from a reference voltage.

2. The radio frequency switch according to claim 1, wherein the control circuit comprises:
a first node configured to receive a signal for enabling the transmit mode; and
an inverter block coupling the first node to a control node of a first transistor having a first conduction node configured to receive the reference voltage.

3. The radio frequency switch according to claim 1, wherein an output node of the charge pump circuit is coupled to a control node of the switching circuit.

4. The radio frequency switch according to claim 2, wherein a second conduction node of the first transistor is coupled to an output node of the charge pump circuit.

5. The radio frequency switch according to claim 2, wherein the control circuit comprises an oscillator coupling the first node to an input node of the charge pump circuit.

6. The radio frequency switch according to claim 1, wherein the reference voltage is ground.

7. The radio frequency switch according to claim 6, wherein the first transistor is an NMOS transistor, and wherein the control circuit comprises:
a first node configured to receive a signal for enabling the transmit mode; and
an inverter block coupling the first node to a control node of a first transistor having a first conduction node configured to receive the reference voltage.

8. The radio frequency switch according to claim 7, wherein the charge pump circuit is configured to deliver a negative voltage on its output node when it receives an alternating signal.

9. The radio frequency switch according to claim 8, wherein:
the inverter block comprises first and second inverters;
the first inverter is configured to receive another reference voltage on a first power supply node of the first inverter and the ground on a second power supply node of the first inverter, the first inverter comprising an input node of the first inverter coupled to the first node, and an output node of the first inverter coupled to a first power supply node of the second inverter; and
the second inverter comprises an input node of the second inverter configured to be coupled to the ground, an output node of the second inverter coupled to the control node of the first transistor, and a second power supply node of the second inverter coupled to the output node of the charge pump circuit.

10. The radio frequency switch according to claim 1, wherein the reference voltage is VDD.

11. The radio frequency switch according to claim 10, wherein the first transistor is a PMOS transistor, and wherein the control circuit comprises:
a first node configured to receive a signal for enabling the transmit mode; and
an inverter block coupling the first node to a control node of a first transistor having a first conduction node configured to receive the reference voltage.

12. The radio frequency switch according to claim 11, wherein the charge pump circuit is configured to deliver a positive voltage higher than VDD on its output node when it receives an alternating signal.

13. The radio frequency switch according to claim 12, wherein the inverter block comprises an inverter circuit having:
an input node configured to receive the reference voltage;
a first power supply node coupled to the output node of the charge pump circuit;
a second power supply node coupled to the first node; and
an output node of the inverter block coupled to the control node of the first transistor.

14. The radio frequency switch according to claim 1, wherein the switching circuit comprises transistors of silicon-on-insulator type.

15. The radio frequency switch according to claim 1, wherein an output node of the charge pump circuit is coupled to the switching circuit via a voltage level shifting circuit reconfigurable in accordance with the charge pump circuit.

16. A radio frequency switch comprising:
a control circuit, configured to:
in a radio frequency signal transmit mode, control a switching circuit with a first state originating from outputs of first and second charge pump circuits; and
in a radio frequency signal receive mode, disable the first and second charge pump circuits and control the switching circuit with a second state originating from a VDD voltage and a ground voltage;
wherein the control circuit comprises:
a first node configured to receive a signal for enabling the transmit mode; and
a first inverter block comprising first and second inverters, and coupling the first node to a control node of an NMOS transistor having a first conduction node configured to receive the ground voltage;
wherein the first inverter comprises a first input node coupled to the first node and a first output node coupled to a first power supply node of the second inverter, and is configured to receive another reference voltage on a first power supply node of the first inverter and the ground voltage on a second power supply node of the first inverter; and
wherein the second inverter comprises a second input node configured to be coupled to ground voltage, a second output node coupled to the control node of the NMOS transistor, and a second power supply node of the second inverter coupled to the first output node; and
a second inverter block comprising an inverter circuit, and coupling the first node to a control node of a PMOS transistor having a second conduction node configured to receive the VDD voltage, wherein the inverter circuit comprises:
a third input node configured to receive the VDD voltage,
a first power supply node of the inverter circuit coupled to the second output node and a second power supply node of the inverter circuit coupled to the first node; and
a third output node coupled to the control node of the PMOS transistor;
the first charge pump circuit, configured to deliver a negative voltage on its output node in response to receiving an alternating signal; and
the second charge pump circuit, configured to deliver a positive voltage higher than the VDD voltage on its output node in response to receiving the alternating signal;
wherein the output nodes of the first and second charge pump circuits are coupled to the switching circuit via a voltage level shifting circuit reconfigurable in accordance with the first or second charge pump circuits.

17. The radio frequency switch according to claim 16, wherein the switching circuit comprises:
N second transistors coupling a transmit circuit output node to an antenna node;
N third transistors coupling the antenna node to a receive circuit input node;
N fourth transistors coupling the ground voltage to the transmit circuit output node; and
N fifth transistors coupling the ground voltage to the receive circuit input node;
wherein the control circuit is configured to control the Nth second and Nth fifth transistors with a respective Nth first signal originating from the voltage level shifting circuit and to control the Nth third and Nth fourth transistors with an Nth second signal complementary to the Nth first signal; and
wherein N is an integer greater than or equal to 1.

18. The radio frequency switch according to claim 17, wherein N is equal to 1, and the switching circuit further comprises:
a second transistor coupling the transmit circuit output node to the antenna node;
a third transistor coupling the antenna node to the receive circuit input node;
a fourth transistor coupling the ground voltage to the transmit circuit output node; and
a fifth transistor coupling the ground voltage to the receive circuit input node;
wherein the control circuit is configured to control the second and fifth transistors with a first signal originating from the voltage level shifting circuit and to control the third and fourth transistors with a second signal complementary to the first signal.

19. The radio frequency switch according to claim 18, wherein the radio frequency switch is in a radio frequency system comprising an antenna coupled to the antenna node.

20. A method of operating a radio frequency switch comprising a control circuit, the method comprising:
in a radio frequency signal transmit mode, controlling a switching circuit, with a first state originating from an output of a charge pump circuit; and
in a radio frequency signal receive mode, disabling the charge pump circuit, and disabling the controlling the switching circuit, with a second state originating from a reference voltage.
